(19) United States
(12) Patent Application Publication
(10) Pub. No.: US 2024/0387419 A1
(43) Pub. Date: Nov. 21, 2024

(54) DIRECT HYBRID BOND PAD HAVING TAPERED SIDEWALL

(71) Applicant: ADEIA SEMICONDUCTOR BONDING TECHNOLOGIES INC., San Jose, CA (US)

(72) Inventors: Pawel Mrozek, San Jose, CA (US); Gaius Gillman Fountain, JR., Youngsville, NC (US)

(21) Appl. No.: 18/319,786

(22) Filed: May 18, 2023

(51) Int. Cl. H01L 23/00; H01L 25/065

(52) U.S. Cl. CPC H01L 24/05; H01L 24/03; H01L 24/08; H01L 24/80; H01L 25/0657; H01L 2224/03614; H01L 2224/0362; H01L 2224/03622; H01L 2224/03845; H01L 2224/05548; H01L 2224/05557; H01L 2224/05558; H01L 2224/05647; H01L 2224/05687; H01L 2224/08121; H01L 2224/08145; H01L 2224/8083; H01L 2224/80895; H01L 2224/80896; H01L 2224/80905; H01L 2225/06527; H01L 2225/06544; H01L 2225/06565; H01L 2924/30105; H01L 2924/3511; H01L 2924/35121

(57) ABSTRACT

An element, a bonded structure that includes the element, and methods of forming the same are disclosed. The element can include a nonconductive field region having a surface defining at least a portion of a bonding surface of the element. The surface of the nonconductive field region is prepared for direct bonding. The element can also include a conductive feature having an upper surface that defines at least a portion of the bonding surface of the element, a lower surface opposite the upper surface, and a sidewall that extends between the upper surface and the lower surface. An angle between the upper surface and the sidewall is about 75° or less. The bonded structure includes the element and a second element directly bonded to one another without an intervening adhesive.

### BACKGROUND

### Field

The field relates to elements, bonded structures, and methods of forming the elements and bonded structures, and, in particular to elements and bonded structures with a direct hybrid bond pad having a tapered sidewall.

### Description of the Related Art

Microelectronic elements, such as integrated device dies or chips, may be mounted or stacked on other elements thereby forming a bonded structure. Direct metal bonding can be conducted at low temperatures and without external pressure. For example, direct hybrid bonding involves directly bonding non-conductive features (e.g., inorganic dielectrics) of different elements together, without intervening adhesives, while or subsequently also directly bonding conductive features (e.g., metal pads or lines) of the elements together. For example, a microelectronic element can be mounted to a carrier, such as an interposer, a reconstituted wafer or element, etc. As another example, a microelectronic element can be stacked on top of another microelectronic element, e.g., a first integrated device die can be stacked on a second integrated device die. Each of the microelectronic elements can have conductive pads for mechanically and electrically bonding the elements to one another. There is a continuing need for improved methods for forming the bonded structure.

### BRIEF DESCRIPTION OF THE DRAWINGS

Specific implementations will now be described with reference to the following drawings, which are provided by way of example, and not limitation.

FIG. 1A is a schematic cross-sectional side view of two elements prior to direct bonding.

FIG. 1B is a schematic cross-sectional side view of the two elements shown in FIG. 1A after direct bonding.

FIG. 2 is a schematic cross-sectional side view of an element according to an embodiment.

FIG. 3 is a schematic cross-sectional side view of bonded elements (a first element and a second element) that at least partially define a bonded structure, according to an embodiment.

FIG. 4A is a schematic cross-sectional side view of a structure that includes a device portion, a back end of line (BEOL) structure disposed over the device portion, a dielectric layer disposed over the BEOL structure, and a patterned resist layer disposed over the dielectric layer.

FIG. 4B is a schematic cross-sectional side view of the structure of FIG. 4A at a first stage of forming cavities.

FIG. 4C is a schematic cross-sectional side view of the structure of FIG. 4A at a second stage of forming the cavities after the first stage.

FIG. 4D is a schematic cross-sectional side view of the structure of FIG. 4A after the cavities are fully formed.

FIG. 5A is a schematic cross-sectional side view of a structure that includes a device portion, a back end of line (BEOL) structure disposed over the device portion, a dielectric layer disposed over the BEOL structure, and a patterned resist layer disposed over the dielectric layer.

FIG. 5B is a schematic cross-sectional side view of the structure of FIG. 5A after cavities are formed.

FIG. 6A shows the structures of FIG. 4B or 5B without the patterned resist layer.

FIG. 6B shows the structure of FIG. 6A after providing a conductive material.

FIG. 6C shows the structure of FIG. 6B after a planarization process.

FIG. 7A is a schematic cross-sectional side view of a portion of an element according to an embodiment.

FIG. 7B is a schematic cross-sectional side view of a portion of an element according to another embodiment.

### DETAILED DESCRIPTION

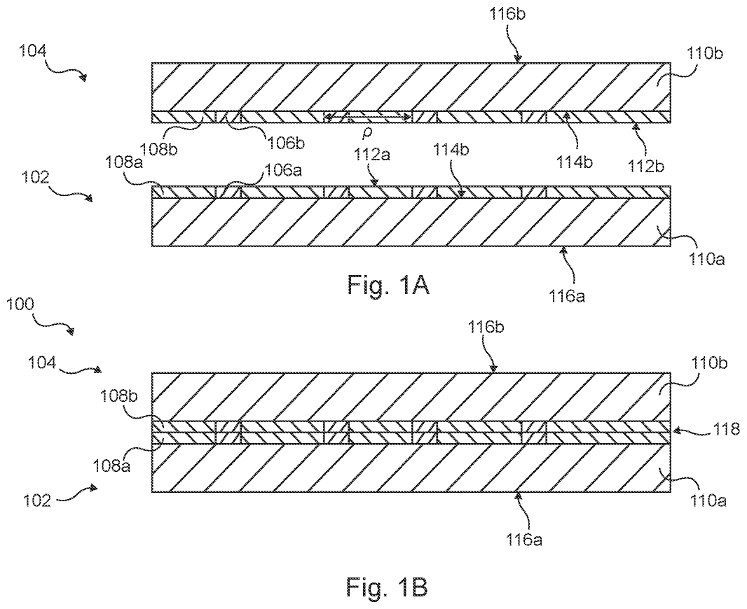

Various embodiments disclosed herein relate to directly bonded (e.g., hybrid bonded) structures in which two or more elements can be directly bonded (e.g., hybrid bonded) to one another without an intervening adhesive. FIGS. 1A and 1B schematically illustrate a process for forming a directly bonded (e.g., hybrid bonded) structure without an intervening adhesive according to some embodiments. In FIGS. 1A and 1B, a bonded structure 100 comprises two elements 102 and 104 that can be directly bonded (e.g., hybrid bonded) to one another at a bond interface 118 without an intervening adhesive. Two or more microelectronic elements 102 and 104 (such as semiconductor elements, including, for example, integrated device dies, wafers, passive devices, individual active devices such as power switches, etc.) may be stacked on or bonded to one another to form the bonded structure 100. Conductive features 106a (e.g., contact pads, traces, exposed ends of vias through substrate electrodes or vias) of the first element 102 may be electrically connected to corresponding conductive features 106b of the second element 104. Any suitable number of elements can be stacked in the bonded structure 100. For example, a third element (not shown) can be stacked on the second element 104, a fourth element (not shown) can be stacked on the third element, and so forth. Additionally or alternatively, one or more additional elements (not shown) can be stacked laterally adjacent one another along the first element 102. In some embodiments, the laterally stacked additional element may be smaller than the second element 104. In some embodiments, the laterally stacked additional element may be two times smaller than the second element 104.

In some embodiments, the elements 102 and 104 are directly bonded (e.g., hybrid bonded) to one another without an intervening adhesive. In various embodiments, a non-conductive field region that includes a non-conductive or dielectric material can serve as a first bonding layer 108a of the first element 102 which can be directly bonded to a corresponding non-conductive field region that includes a non-conductive or dielectric material serving as a second bonding layer 108b of the second element 104 without an intervening adhesive. The non-conductive bonding layers 108a and 108b can be disposed on respective front sides 114a and 114b of device portions 110a and 110b, such as a semiconductor (e.g., silicon) portion of the elements 102, 104, or back-end-of-line (BEOL) interconnect layers over such semiconductor portions. Active devices (e.g., transistors) and/or circuitry can be patterned and/or otherwise disposed in or on the device portions 110a and 110b. Active devices and/or circuitry can be disposed at or near the front sides 114a and 114b of the device portions 110a and 110b, and/or at or near opposite backsides 116a and 116b of the device portions 110a and 110b. Bonding layers can be provided on front sides and/or back sides of the elements, either at the wafer level during device fabrication, or in a subsequent process, such as in a redistribution layer (RDL) formation in a packaging facility. The non-conductive material can be referred to as a non-conductive bonding region or bonding layer 108a of the first element 102. In some embodiments, the non-conductive bonding layer 108a of the first element 102 can be directly bonded to the corresponding non-conductive bonding layer 108b of the second element 104 using dielectric-to-dielectric bonding techniques. For example, non-conductive or dielectric-to-dielectric bonds may be formed without an intervening adhesive using the bonding techniques disclosed at least in U.S. Pat. Nos. 9,564,414; 9,391,143; and 10,434,749, the entire contents of each of which are incorporated by reference herein in their entirety and for all purposes. It should be appreciated that in various embodiments, the bonding layers 108a and/or 108b can comprise a non-conductive material such as a dielectric material (e.g., silicon oxide), or an undoped semiconductor material (e.g., undoped silicon). Suitable dielectric bonding surface or materials for direct bonding include but are not limited to inorganic dielectrics including silicon (such as silicon oxide, silicon nitride, or silicon oxynitride), or carbon (such as silicon carbide, silicon oxycarbonitride, low K dielectric materials, SiCOH dielectrics, silicon carbonitride, diamond-like carbon or a material comprising a diamond surface). Such carbon-containing ceramic materials can be considered inorganic, despite the inclusion of carbon. In some embodiments, the dielectric materials do not comprise polymer materials, such as epoxy, resin or molding materials.

In some embodiments, the device portions 110a and 110b can have a significantly different coefficients of thermal expansion (CTEs) defining a heterogenous structure. The CTE difference between the device portions 110a and 110b, and particularly between bulk semiconductor, typically single crystal portions of the device portions 110a, 110b, can be greater than 5 ppm or greater than 10 ppm. For example, the CTE difference between the device portions 110a and 110b can be in a range of 5 ppm to 100 ppm, 5 ppm to 40 ppm, 10 ppm to 100 ppm, or 10 ppm to 40 ppm. In some embodiments, one of the device portions 110a and 110b can comprise optoelectronic single crystal materials, including perovskite materials, that are useful for optical piezoelectric or pyroelectric applications, and the other of the device portions 110a, 110b comprises a more conventional substrate material. For example, one of the device portions 110a, 110b comprises lithium tantalate (LiTaO3) or lithium niobate (LiNbO3), and the other one of the device portions 110a, 110b comprises silicon, quartz, fused silica glass, sapphire, or a glass. In other embodiments, one of the device portions 110a and 110b comprises a III-V single semiconductor material, such as gallium arsenide (GaAs) or gallium nitride (GaN), and the other one of the device portions 110a and 110b can comprise a non-III-V semiconductor material, such as silicon, or can comprise other materials with similar CTE, such as quartz, fused silica glass, sapphire, or a glass.

In various embodiments, direct bonds (e.g., hybrid bonds) can be formed without an intervening adhesive. For example, nonconductive bonding surfaces 112a and 112b can be polished to a high degree of smoothness. The nonconductive bonding surfaces 112a and 112b can be polished using, for example, chemical mechanical polishing (CMP). The roughness of the polished bonding surfaces 112a and 112b can be less than 30 Å rms. For example, the roughness of the bonding surfaces 112a and 112b can be in a range of about 0.1 Å rms to 15 Å rms, 0.5 Å rms to 10 Å rms, or 1 Årms to 5 Å rms. The bonding surfaces 112a and 112b can be cleaned and exposed to a plasma and/or etchants to activate the surfaces 112a and 112b. In some embodiments, the surfaces 112a and 112b can be terminated with a species after activation or during activation (e.g., during the plasma and/or etch processes). Without being limited by theory, in some embodiments, the activation process can be performed to break chemical bonds at the bonding surfaces 112a and 112b, and the termination process can provide additional chemical species at the bonding surfaces 112a and 112b that improves the bonding energy during direct bonding (e.g., hybrid bonding). In some embodiments, the activation and termination are provided in the same step, e.g., a plasma to activate and terminate the surfaces 112a and 112b. In other embodiments, the bonding surfaces 112a and 112b can be terminated in a separate treatment to provide the additional species for direct bonding (e.g., hybrid bonding). In various embodiments, the terminating species can comprise nitrogen. For example, in some embodiments, the bonding surface(s) 112a, 112b can be exposed to a nitrogen-containing plasma. In some embodiments, activation and/or termination can be achieved by exposure to oxygen-containing plasma. Further, in some embodiments, the bonding surfaces 112a and 112b can be exposed to fluorine. For example, there may be one or multiple fluorine peaks at or near a bond interface 118 between the first and second elements 102, 104. Thus, in the bonded structure 100, the bond interface 118 between two non-conductive materials (e.g., the bonding layers 108a and 108b) can comprise a very smooth interface with higher nitrogen content and/or fluorine peaks at the bond interface 118. Additional examples of activation and/or termination treatments may be found throughout U.S. Pat. Nos. 9,564,414; 9,391,143; and 10,434,749, the entire contents of each of which are incorporated by reference herein in their entirety and for all purposes. The roughness of the polished bonding surfaces 112a and 112b can be slightly rougher (e.g., about 1 Å rms to 30 Å rms, 3 Å rms to 20 Å rms, or possibly rougher) after an activation process.

In various embodiments, conductive features 106a of the first element 102 can also be directly bonded to corresponding conductive features 106b of the second element 104 without an intervening adhesive (e.g., without solder or other conductive adhesive intervening between the conductive features 106a, 106b). For example, a direct bonding (e.g., hybrid bonding) technique can be used to provide conductor-to-conductor direct bonds along the bond interface 118 that includes covalently bonded non-conductive-to-non-conductive (e.g., dielectric-to-dielectric) surfaces, prepared as described above. In various embodiments, the conductor-to-conductor (e.g., conductive feature 106a to conductive feature 106_{b}) bonds and the dielectric-to-dielectric bonds can be formed using the direct bonding (e.g., hybrid bonding) techniques disclosed at least in U.S. Pat. Nos. 9,716,033 and 9,852,988, the entire contents of each of which are incorporated by reference herein in their entirety and for all purposes. In direct bonding (e.g., hybrid bonding) embodiments described herein, conductive features are provided within non-conductive bonding layers, and both conductive and nonconductive features are prepared for direct bonding (e.g., hybrid bonding), such as by the planarization, activation and/or termination treatments described above. Thus, the bonding surface prepared for direct bonding (e.g., hybrid bonding) includes both conductive and non-conductive features.

For example, non-conductive (e.g., dielectric) bonding surfaces 112a, 112b (for example, inorganic dielectric surfaces) can be prepared and directly bonded to one another without an intervening adhesive as explained above. Conductive contact features (e.g., conductive features 106a and 106b which may be at least partially surrounded by non-conductive dielectric field regions within the bonding layers 108a, 108b) may also directly bond to one another without an intervening adhesive. In various embodiments, the conductive features 106a, 106b can comprise discrete pads or traces at least partially embedded in the non-conductive field regions. In some embodiments, the conductive contact features can comprise exposed contact surfaces of through substrate vias (e.g., through silicon vias (TSVs)). In some embodiments, the respective conductive features 106a and 106b can be recessed below exterior (e.g., upper) surfaces (non-conductive bonding surfaces 112a and 112b) of the dielectric field region or non-conductive bonding layers 108a and 108b, for example, recessed by less than 30 nm, less than 20 nm, less than 15 nm, or less than 10 nm, for example, recessed in a range of 2 nm to 20 nm, or in a range of 4 nm to 10 nm. The recess can be at or near the middle or center of the cavity in which the conductive features 106a, 106b are disposed, and, additionally or alternatively, can extend or be disposed along sides of the cavity in which the conductive features 106a, 106b are disposed. In various embodiments, prior to direct bonding (e.g., hybrid bonding), the recesses in the opposing elements can be sized such that the total gap between opposing contact pads is less than 15 nm, or less than 10 nm. The non-conductive bonding layers 108a and 108b can be directly bonded to one another without an intervening adhesive at room temperature in some embodiments and, subsequently, the bonded structure 100 can be annealed. Upon annealing, the conductive features 106a and 106b can expand and contact one another to form a metal-to-metal direct bond. Beneficially, the use of Direct Bond Interconnect, or DBI®, techniques commercially available from Adeia of San Jose, CA, can enable high density of conductive features 106a and 106b to be connected across the bond interface 118 (e.g., small or fine pitches for regular arrays). In some embodiments, a pitch p of the conductive features 106a and 106b, such as conductive traces embedded in the bonding surface of one of the bonded elements, may be less than 100 μm or less than 10 μm or even less than 2 μm. For some applications, the ratio of the pitch of the conductive features 106a and 106b to one of the dimensions (e.g., a diameter) of the bonding pad is less than is less than 20, or less than 10, or less than 5, or less than 3 and sometimes desirably less than 2. In other applications, the width of the conductive traces embedded in the bonding surface of one of the bonded elements may range between about 0.3 μm to 50 μm, e.g., in a range of about 0.3 μm to 20 μm, about 0.3 μm to 3 μm, about 0.5 μm to 50 μm, about 0.75 μm to 25 μm, or about 1 μm to 5 μm. In various embodiments, the conductive features 106a and 106b and/or traces can comprise copper or copper alloys, although other metals may be suitable. For example, the conductive features disclosed herein, such as the conductive features 106a and 106b, can comprise aluminum or a fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

Thus, in direct bonding (e.g., hybrid bonding) processes, the first element 102 can be directly bonded (e.g., hybrid bonded) to the second element 104 without an intervening adhesive. In some arrangements, the first element 102 can comprise a singulated element, such as a singulated integrated device die. In other arrangements, the first element 102 can comprise a carrier or substrate (e.g., a wafer) that includes a plurality (e.g., tens, hundreds, or more) of device regions that, when singulated, form a plurality of integrated device dies. Similarly, the second element 104 can comprise a singulated element, such as a singulated integrated device die. In other arrangements, the second element 104 can comprise a carrier or substrate (e.g., a wafer). The embodiments disclosed herein can accordingly apply to wafer-to-wafer (W2W), die-to-die (D2D), or die-to-wafer (D2W) bonding processes. In W2W processes, two or more wafers can be directly bonded (e.g., hybrid bonded) to one another and singulated using a suitable singulation process. After singulation, side edges of the singulated structure (e.g., the side edges of the two bonded elements) may be substantially flush and may include markings indicative of the common singulation process for the bonded structure (e.g., saw markings if a saw singulation process is used).

As explained herein, the first and second elements 102 and 104 can be directly bonded (e.g., hybrid bonded) to one another without an intervening adhesive, which is different from a deposition process and results in a structurally different interface compared to a deposition. In one application, a width of the first element 102 in the bonded structure is similar to a width of the second element 104. In some other embodiments, a width of the first element 102 in the bonded structure 100 is different from a width of the second element 104. Similarly, the width or area of the larger element in the bonded structure may be at least 10% larger than the width or area of the smaller element. The first and second elements 102 and 104 can accordingly comprise non-deposited elements. Further, bonded structures 100, unlike deposited layers, can include a defect region along the bond interface 118 in which nanometer-scale voids (nanovoids) are present. The nanovoids may be formed due to activation of the bonding surfaces 112a and 112b (e.g., exposure to a plasma). As explained above, the bond interface 118 can include concentration of materials from the activation and/or last chemical treatment processes. For example, in embodiments that utilize a nitrogen plasma for activation, a nitrogen peak can be formed at the bond interface 118. The nitrogen peak can be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen peak can be formed at the bond interface 118. In some embodiments, the bond interface 118 can comprise silicon oxynitride, silicon oxycarbonitride, or silicon carbonitride. As explained herein, the direct bond can comprise a covalent bond, which is stronger than van Der Waals bonds. The bonding layers 108a and 108b can also comprise polished surfaces that are planarized to a high degree of smoothness.

In various embodiments, the metal-to-metal bonds between the conductive features 106a and 106b can be joined such that metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. The bond interface 118 can extend substantially entirely to at least a portion of the bonded conductive features 106a and 106b, such that there is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b, for example, as described in U.S. Pat. No. 11,195,748, which is incorporated by reference herein in its entirety and for all purposes.

As described above, the non-conductive bonding layers 108a, 108b can be directly bonded to one another without an intervening adhesive and, subsequently, the bonded structure 100 can be annealed. Anneal temperatures can vary depending upon thermal budgets for the devices, size of the conductive features 106a, 106b, size of the gap between conductive features 106a, 106b, materials for the conductive features 106a, 106b and surrounding non-conductive layers 108a, 108b and their relative CTEs, etc. Example temperatures for annealing include between about 50° C. and 400° C., between about 100° C. and 300° C., and between about 150° C. and 250° C. Upon annealing, the conductive features 106a, 106b can expand and contact one another to form a metal-to-metal direct bond. In some embodiments, the materials of the conductive features 106a, 106b can interdiffuse during the annealing process.

Embodiments described herein can reduce stress in the conductive features 106a, 106b. Contact or bonding pads shaped as described hereinbelow can reduce residual stresses compared to conventional pads, and consequently reduce wafer or die bowing.

As described herein, the bonding surfaces 112a and 112b of the element can be polished in preparation for direct bonding (e.g., hybrid bonding). When the bonding surfaces 112a and 112b of the non-conductive bonding layers 108a, 108b are polished, there can be dielectric rounding at a region of the bonding surfaces 112a and 112b adjacent to the conductive features 106a, 106b. Dielectric rounding can decrease the overall bonding strength and integrity of the bond. This can lead to delamination or separation of the bonded layers over time, especially when the bonded structure is subjected to thermal or mechanical stress. Also, dielectric rounding can lead to the formation of voids or air gaps between the bonded layers, which can negatively impact the electrical and optical properties of the device. Various embodiments disclosed herein relate to structures that can prevent and/or reduce formation of dielectric rounding during the polishing process by reducing stress at the edges of conductive features 106a, 106b.

As described above, the use of the direct bonding (e.g., hybrid bonding) techniques described herein can enable extremely fine pitch between adjacent conductive features 106a and 106b, and/or small pad sizes. However, when the pitch between adjacent conductive features 106a and 106b is small, there can be undesirable parasitic capacitance between the adjacent conductive features 106a and 106b, especially for higher frequency performance. Various embodiments disclosed herein relate to structures that can reduce such parasitic capacitance without increasing the pitch.

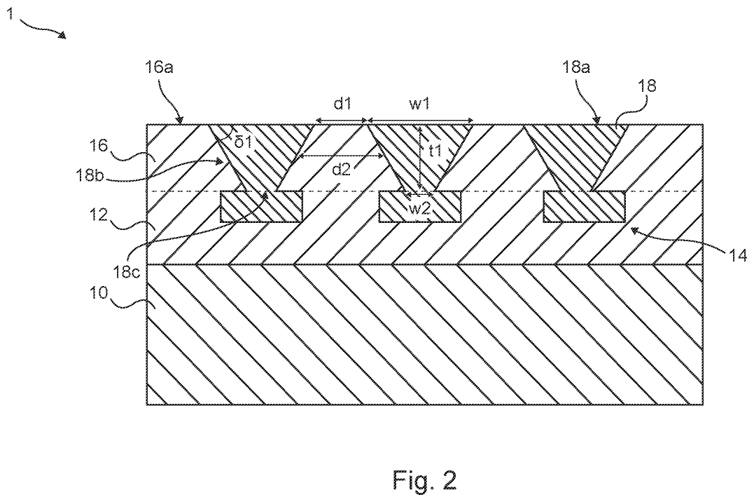

FIG. 2 is a schematic cross-sectional side view of an element 1 according to an embodiment. The element 1 can include a device portion 10, a back end of line (BEOL) structure 12 that includes an interconnect structure 14, a dielectric layer 16, and a conductive feature (e.g., conductive pads 18). As is known in the art, for an integrated circuit, the BEOL structure 12 can include multiple interconnect layers, including patterned traces and vias separated from one another by interlevel dielectrics (ILD). However, the skilled artisan will appreciate that principles and advantages taught herein are applicable to much simpler structures, such as individual surface mount devices, which may include simple contact leads without BEOL layers. A contact surface of the element 1 includes a surface 16a of the dielectric layer 16 and an upper surface 18a of the contact pad 18, which can also be referred to as a bonding or contact surface. The dielectric layer 16 can also be referred to as a nonconductive field region.

The device portion 10 can be a semiconductor (e.g., silicon) portion of the element 1. Active devices (e.g., transistors) and/or circuitry can be patterned and/or otherwise disposed in or on the device portion 10. While illustrated as a landing pad, the skilled artisan will appreciate that the interconnect structure 14 can take the form of routing metal lines or traces, an interlevel via, a through substrate via, or a landing pad that can electrically connect to the conductive pad 18. The interconnect structure 14 can be part of or above the BEOL structure 12 as shown, or can be part of or above a RDL. In some embodiments, the via of the interconnect structure 14 can have a width in a range of, for example, about 0.1 μm to 0.5 μm, or about 0.2 μm to 0.4 μm.

The dielectric layer 16 has a bonding surface 16a, which can be polished to a high degree of smoothness. The bonding surface 16a can be polished using, for example, CMP. The roughness of the bonding surface 16a can be less than 30 Årms. For example, the roughness of the bonding surface 16a can be in a range of about 0.1 Å rms to 15 Å rms, about 0.5 Å rms to 10 Å rms, or about 1 Å rms to 5 Å rms.

The contact pad 18, such as a copper pad, has the upper or bonding surface 18a, a sidewall 18b, and a lower side or surface 18c. The sidewall 18b can extend between the upper surface 18a and the lower surface 18c. An internal angle δ1 between the bonding surface 18a and the sidewall 18b is acute, and can be equal to or less than about 75°, less than about 70°, less than about 60°, or less than about 50°. For example, the angle δ1 between the bonding surface 18a and the sidewall 18b can be in a range of about 30° to 75°, about 35° to 75°, about 30° to 70°, about 35° to 70°, about 30° to 60°, about 35° to 60°, about 30° to 50°, or about 35° to 50°. As an example, the angle δ1 between the bonding surface 18a and the sidewall 18b can be about 45°, such as 45±5°. In some embodiments, there can be an intervening layer (not shown) between the contact pad 18 and the dielectric layer 16. The intervening layer can include a seed layer and/or a barrier layer (e.g., a diffusion barrier layer). The intervening layer can have a multi-layer structure, in some embodiments.

In some embodiments, a cavity formed in the dielectric layer 16 in which the contact pad 18 is disposed can be formed by way of dry etching (e.g., plasma etching) using a patterned photoresist, whether or not directional, or by way of controlled isotropic etching (e.g., wet etching or certain dry vapor etching). To form conventional contact pads of an element for direct bonding (e.g., hybrid bonding), particularly for high density pads, a skilled artisan may avoid highly sloped sidewalls, in order to form a precisely sized contact pads for direct bonding (e.g., hybrid bonding). Rather, contact pads for direct bonding (e.g., hybrid bonding) typically are arranged to have close to 90° angles, or close to vertical sidewalls relative to a horizontal contact surface of the element. However, in the present disclosure, the contact pad 18 is arranged to have highly sloped sidewalls, with a relatively small angle δ1.

Forming the cavity in the dielectric layer 16 for the contact pad 18 to have sloped sidewalls as disclosed herein can facilitate significant advantages, as such the angles can reduce stress and lead to the formation of dielectric rounding during a polishing (e.g., CMP) process.

The bonding or upper surface 18a of the contact pad 18 has a width w1 and the lower side or surface 18c of the contact pad 18 that contacts the interconnect structure 14 has a width w2 that is smaller than the width w1. In some embodiments, the contact pad 18 can be formed at a wafer level, and the width w1 of the bonding surface 18a of the contact pad 18 can be in a range of about 0.5 μm to 20 μm, about 0.5 μm to 10 μm, about 0.5 μm to 5 μm, about 0.5 μm to 1 μm, about 1 μm to 5 μm, or about 1 μm to 10 μm. In some embodiments, the contact pad 18 can be formed at a package level, and the width w1 of the bonding surface 18a of the contact pad 18 can be in a range of 20 μm to 200 μm, 20 μm to 100 μm, 40 μm to 200 μm, or 400 μm to 100 μm. Due to the tapered shape, the width w1 may be adjusted during a polishing process—when the contact pad 18 is polished more, the width w1 of the contact pad 18 can be smaller.

The contact pad 18 has a thickness t1. In some embodiments, a thickness of the dielectric layer 16 can be equal to or greater than the thickness t1. For example, the thickness t1 of the contact pad 18 can be in a range of 0.5 μm to 3 μm, 1 μm to 3 μm, or 1 μm to 2 μm. In some embodiments, the bonding surface 18a can be recessed relative to the bonding surface 16a of the dielectric layer 16. For example, the bonding surface 18a can be recessed relative to the bonding surface 16a of the dielectric layer 16 in a range of 2 nm to 20 nm, or in a range of 4 nm to 10 nm.

A distance d1 between the bonding surfaces 18a of adjacent contact pads 18 can be measured at the bonding surface 16a, whether or not the contact pad 18 is recessed. An average distance d2 is an average distance between sidewalls 18b of the adjacent contact pads 18. If the internal angle δ1 between the bonding surface 18a and the sidewall 18b of the contact pad were 90°, the distance d1 and the average distance d2 would be the same. However, because the sidewall 18b has an acute angle δ1 as disclosed herein, the average distance d2 is greater than the distance d1 at the upper surface. Therefore, parasitic capacitance can be reduced when the sidewall 18b is sloped inwardly as disclosed herein.

The element 1 can be bonded to another element (a second element) to form a bonded structure. In some embodiments, the second element can have an identical or generally similar structure as the element 1. In some other embodiments, the second element can be configured to directly bond (e.g., hybrid bond) to the element 1 but have a different structure from the element 1. As noted above, the elements being bonded can individually be identical or different dies, wafers, passive or active components, etc.

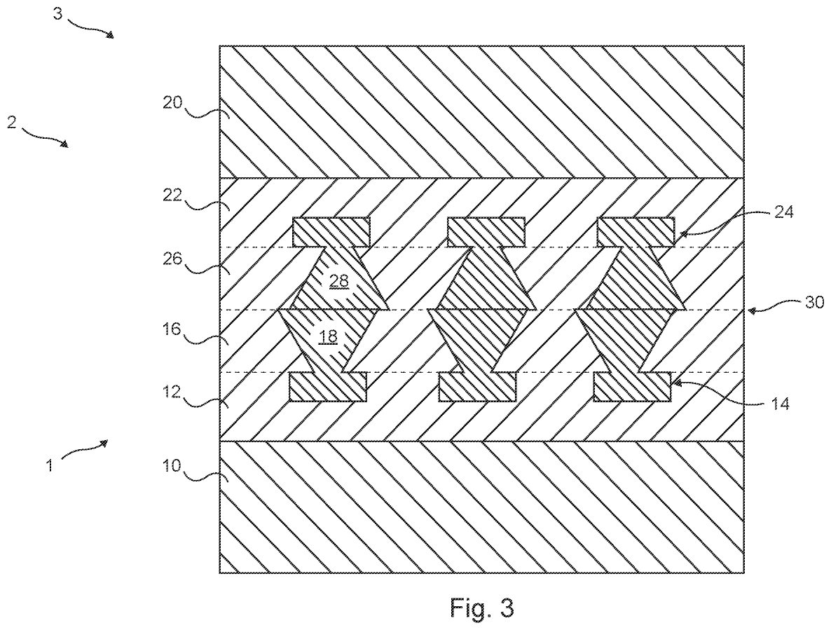

FIG. 3 is a schematic cross-sectional side view of bonded elements (a first element 1 and a second element 2) that at least partially define a bonded structure 3, according to an embodiment. Unless otherwise noted, similarly named or labeled components of FIG. 3 can be the same as or generally similar to the corresponding components of FIG. 2.

The first element 1 can include a first device portion 10, a first BEOL structure 12 that includes a first interconnect structure 14, a first dielectric layer 16, and a first conductive feature (e.g., conductive pads 18). The second element 2 can include a second device portion 20, a second BEOL structure 22 that includes a second interconnect structure 24, a second dielectric layer 26, and a second conductive feature (e.g., conductive pads 28). The first and second elements 1, 2 can be directly bonded (e.g., hybrid bonded) to one another along a bond interface 30 without an intervening adhesive. The first and second dielectric layers 16, 26 can be directly bonded to one another along the bond interface 30 without an intervening adhesive, and the first and second conductive pads 18, 28 can be directly bonded to one another along the bond interface 30 without an intervening adhesive.

In some arrangements, the first element 1 can comprise a singulated element, such as a singulated integrated device die. In other arrangements, the first element 1 can comprise a carrier or substrate (e.g., a wafer) that includes a plurality (e.g., tens, hundreds, or more) of device regions that, when singulated, form a plurality of integrated device dies. Similarly, the second element 2 can comprise a singulated element, such as a singulated integrated device die. In other arrangements, the second element 2 can comprise a carrier or substrate (e.g., a wafer). The embodiments disclosed herein can accordingly apply to wafer-to-wafer, die-to-die, or die-to-wafer bonding processes. In wafer-to-wafer processes, two or more wafers can be directly bonded (e.g., hybrid bonded) to one another and subsequently singulated using a suitable singulation process. After singulation, side edges of the singulated structure (e.g., the side edges of the two bonded elements) may be substantially flush and may include markings indicative of the common singulation process for the bonded structure (e.g., saw markings if a saw singulation process is used).

There can be any suitable number of the conductive pads 18 included in the first element 1. The conductive pads 18 can be distributed at or near a bonding surface of the first element 1 in any suitable manner. For example, the conductive pads 18 can be distributed evenly or periodically, non-periodically, symmetrically, non-symmetrically, and/or randomly along the bonding surface of the first second element 1. Likewise, there can be any suitable number of the conductive pads 28 included in the second element 2. The conductive pads 218 can be distributed at or near a bonding surface of the second element 2 in any suitable manner. For example, the conductive pads 28 can be distributed evenly or periodically, non-periodically, symmetrically, non-symmetrically, and/or randomly along the bonding surface of the second element 2. In some embodiments, the conductive pads 18, 28 can be distributed so as to reduce or control parasitic capacitance between two or more of the conductive pads 18, 28 and/or to reduce or control stress. At least some pads 18 of the first element 1 correspond in location to pads 28 of the second element, so that they can be aligned for hybrid direct bonding. However, not all pads 18, 28 on the elements 1, 2 need to be aligned with one another, particularly when the elements include dummy pads.

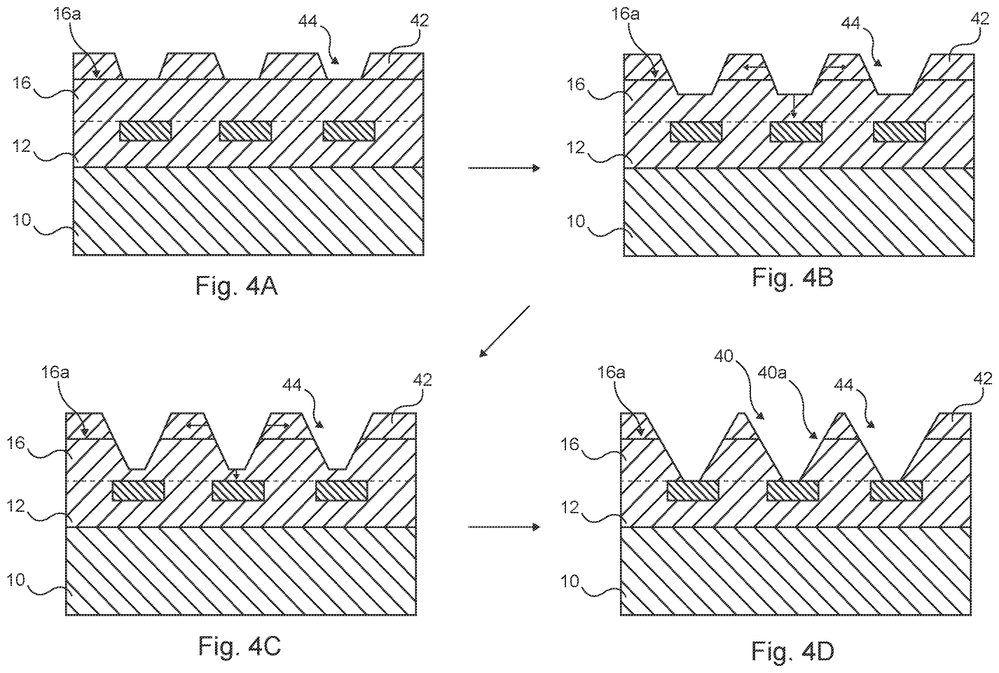

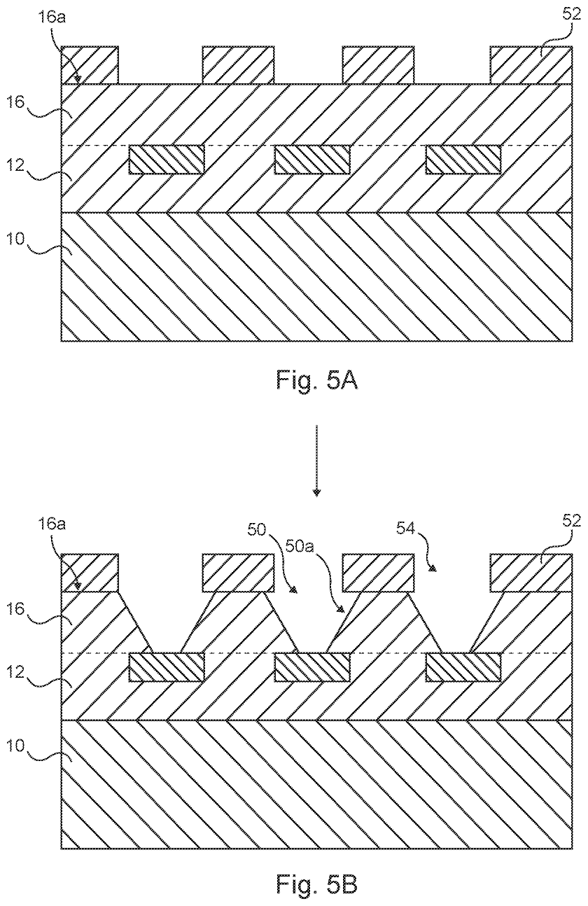

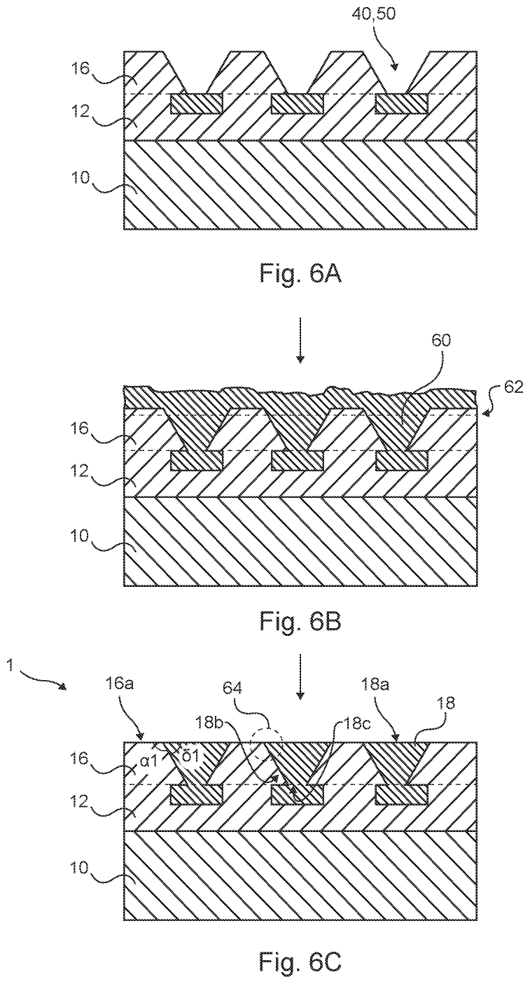

Methods of forming conductive pads with an acute internal angle δ1 between a bonding surface and a sidewall in a range of, for example, 30° to 75°, 35° to 75°, 30° to 70°, 35° to 70°, 30° to 60°, 35° to 60°, 30° to 50°, or 35° to 50°, will be described referring to FIGS. 4A-6C. FIGS. 4A and 4B show a process of forming a plurality of cavities 40 according to an embodiment. FIGS. 5A and 5B show another process of forming a plurality of cavities 50 according to an embodiment. FIGS. 6A to 6C show a process of defining a bonding surface of an element 1 according to an embodiment.

FIG. 4A is a schematic cross-sectional side view of a structure that includes a device portion 10, a BEOL structure 12 disposed over the device portion, a dielectric layer 16 disposed over the BEOL structure 12, and a patterned resist layer 42 disposed over the dielectric layer 16. FIG. 4B is a schematic cross-sectional side view of the structure at a first stage of forming the cavities 40. FIG. 4C is a schematic cross-sectional side view of the structure at a second stage of forming the cavities 40 after the first stage. FIG. 4D is a schematic cross-sectional side view of the structure after the cavities 40 are fully formed. The patterned resist layer 42 can have openings 44 that are shaped in accordance with a desired shape of the cavity 40 formed in FIG. 4D.

The patterned resist layer 42 can be patterned by way of photolithography. The patterned resist layer 42 can be patterned by using different baking methods to control the sidewall angle, or using a multi-exposure (e.g., a double exposure) method having a first exposure with the pattern and a second blanket exposure followed by a development process. Thus, known techniques can provide a controlled slope shape for the photoresist at the openings 44. The resist layer 42 can be used directly as a mask, or its pattern can be transferred to a hard mask layer prior to etching of the dielectric layer 16. As will be understood by the skilled artisan, similar effects can be obtained by providing a stepped profile for the resist.

Exposed areas of the dielectric layer 16 can be etched away by way of dry etching, such as reactive ion etching (RIE) or deep reactive ion etching (DRIE). The etching process can remove materials from the dielectric layer 16 in a controlled manner, following the patterned resist layer 42 as a guide. As the etching progresses, the shaped photoresist is also eroded, withdrawing and widening (as illustrated with horizontal arrows in FIGS. 4B and 4C) the openings as the etch into the dielectric layer 16 proceeds. Thus, in later stages of the etch, the dielectric layer 16 at outer edges of the openings 44 are newly exposed to the etch, and thus etched for a shorter time, while central portions of the openings 44 are exposed from the beginning and thus etched for a longer time (generally in a direction shown with a vertical arrow in FIGS. 4B and 4C). Accordingly, tapered sidewalls 40a of the cavity 40 can be formed. The etching process can be designed to be anisotropic. In addition to engineering the shape of the resist, the shape of the etched cavities 40 can be influenced by the selectivity between resist and exposed dielectric of any chemical component of the etch. Thus, the slope of the openings can be controlled.

FIG. 5A is a schematic cross-sectional side view of a structure that includes a device portion 10, a BEOL structure 12 disposed over the device portion, a dielectric layer 16 disposed over the BEOL structure 12, and a patterned resist layer 52 disposed over the dielectric layer 16. FIG. 5B is a schematic cross-sectional side view of the structure after the cavities 50 are formed. The patterned resist layer 52 can be pattered by way of photolithography. In contrast to the anisotropic etching process described with respect to FIGS. 4A to 4D, FIGS. 5A and 5B show an isotropic etching process (e.g., an isotropic wet etching or isotropic vapor etching process) for forming the cavities 50.

Exposed areas of the dielectric layer 16 can be etched away by use of a chemical etchant solution that can selectively dissolve the dielectric material of the dielectric layer 16 to thereby form the cavity 50 with a tapered sidewall 50a. The etchant solution can be chosen to have a relatively high selectivity for the dielectric material over the patterned resist layer 52, so that the patterned resist layer 52 can act as a mask to guide the etching process. In some embodiments, the etchant solution can include hydrofluoric acid. For example, the etchant solution can be a mixture of hydrofluoric acid and water, such as 1:10 HF:H₂O, or buffered HF.

In certain isotropic etching processes, a tapered sidewall in a cavity can naturally occur. Typically such tapered sidewalls are avoided or minimized in metallization processes, particularly for fine dimensions, in order to have vertical sidewalls and thus better fidelity between the mask openings and the metal dimensions. In the illustrated embodiment, the isotropic etch etches the dielectric layer 16 both vertically and horizontally. In some embodiments, rates of the vertical and horizontal etching may be controlled. The rates of the vertical and horizontal etching may be affected at least in part by, for example, resist adhesion and/or dielectric structural properties of the dielectric layer 16. The horizontal component of the etching can occur for a longer duration at a top portion of the dielectric layer 16 closer to the bonding surface 16a than a lower portion of the dielectric layer 16 closer to the BEOL structure 12. The duration of the horizontal component of the etching can be gradually shorter as it gets closer to the lower portion. Therefore, the dielectric layer 16 can be etched less in the horizontal direction at the lower portion than the top portion so as to define the tapered sidewall 50a The outer edges of the cavities 50 thus extend under the resist 52, and those newly exposed dielectric surfaces are exposed to the etch for less time than central portions of the openings 54, and as a result the cavities 50 have sloped sidewalls.

FIG. 6A shows the structures of FIGS. 4B and 5B without the patterned resist layer 42 or 52. FIG. 6B shows the structure of FIG. 6A after providing a conductive material 60. The conductive material 60 can be provided at least partially in the cavities 40, 50. In some embodiments, the conductive material 60 can be provided to overfill the cavities 40, 50 such that at least a portion of the dielectric layer 16 over the bonding surface 16a is covered by the conductive material 60. The dashed line 62 indicates a target grind or polish stop line for forming a bonding surface of the element 1.

In some embodiments, an intervening layer (not shown) can be provided between the contact pad 18 and the dielectric layer 16. The intervening layer can include a seed layer and/or a barrier layer (e.g., a diffusion barrier layer). The intervening layer can have a multi-layer structure, in some embodiments.

FIG. 6C shows the element 1 after a planarization process (e.g., a CMP process). In the planarization process, at least a portion of the conductive material 60 and/or at least a portion of the dielectric layer 16 can be removed. The bonding surface 16a of the dielectric layer 16 can be polished to a high degree of smoothness. The bonding surface 16a can be polished to have a surface roughness in a range of about 0.1 Å rms to 15 Å rms, 0.5 Å rms to 10 Å rms, or 1 Å rms to 5 Å rms. In some embodiments, the upper surface 18a of the contact pad 18 can be recessed (not shown) relative to the bonding surface 16a of the dielectric layer 16. For example, the bonding surface 18a can be recessed relative to the bonding surface 16a of the dielectric layer 16 in a range of 2 nm to 20 nm, or in a range of 4 nm to 10 nm.

An acute internal angle δ1 between the bonding surface 18a and the pad sidewall 18b can be equal to or less than 75°, 70°, 60°, or 50°. For example, the angle δ1 between the bonding surface 18a and the sidewall 18b can be in a range of 30° to 75°, 35° to 75°, 30° to 70°, 35° to 70°, 30° to 60°, 35° to 60°, 30° to 50°, or 35° to 50°. An obtuse external angle α1 between the dielectric bonding surface 16a and the sidewall 40a, 50a of the cavity 40, 50 can be about 180° minus the internal angle δ1 between the bonding surface 18a and the sidewall 18b. The external angle α1 between the dielectric bonding surface 16a and the sidewall 40a, 50a in various embodiments disclosed herein can be more than 100°, 105°, 110°, 120°, or 130°. For example, the angle α1 between the dielectric bonding surface 16a and the sidewall 40a, 50a of the cavity 40, 50 can be in a range of 105° to 150°, 105° to 145°, 110° to 150°, 110° to 145°, 120° to 150°, 120° to 145°, 130° to 150°, or 130° to 145°.

A known problem associated with a planarization process (e.g., a CMP process) in a conventional element is dielectric rounding or eroding at or near a portion between a bonding surface of a dielectric layer and a bonding surface of a conductive pad. During the CMP process, the material removal rate can vary depending on, for example, the local surface topography of the element and stresses in the dielectric and conductive materials exposed to the polish. These stresses can cause the polishing pad to preferentially polish the dielectric material at the corners adjacent the contact pad, resulting in the rounding of the dielectric corners. The embodiments of the present disclosure can prevent or mitigate formation of dielectric rounding at or near a corner 64 between the bonding surface 16a of the dielectric layer 16 and the bonding surface 18a of the conductive pad 18. Selecting the angles α1, δ1 of the sidewalls 40a, 50a, 18b as disclosed herein can provide such advantages.

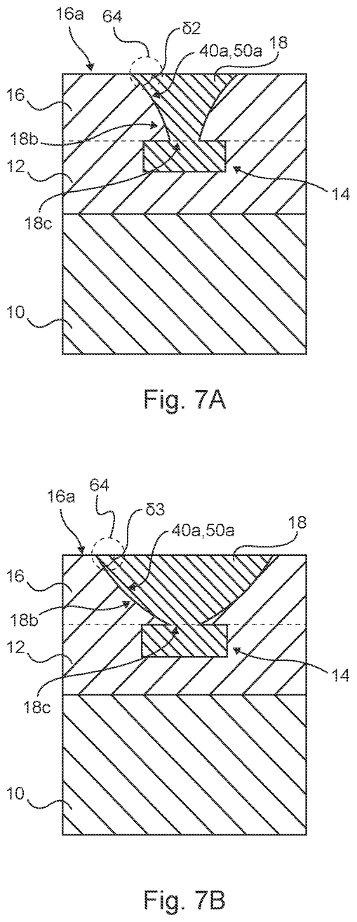

In some embodiments, the sidewall 40a, 50a of the cavity 40, 50 can have a generally straight line and/or a conical profile. In some other embodiments, the sidewall 40a, 50a of the cavity 40, 50 can have curvature (see FIGS. 7A and 7B) or steps. The sidewall 18b of the conductive pad 18 can conform to the sidewall 40a, 50a of the cavity 40, 50.

FIG. 7A is a schematic cross-sectional side view of a portion of an element according to an embodiment. FIG. 7B is a schematic cross-sectional side view of a portion of an element according to another embodiment. Unless otherwise noted, similarly named or labeled components of FIGS. 7A and 7B can be the same as or generally similar to the corresponding components of FIG. 2. In FIG. 7A, the sidewall 40a, 50a has a convex curvature and the sidewall 18b of the conductive pad 18 has a concave curvature. In FIG. 7B, the sidewall 40a, 50a has a concave curvature and the pad sidewall 18b has a convex curvature. The angles δ2, δ3 between the bonding surface 18a and the sidewall 18b can be the same as or generally similar to the angle δ1 disclosed herein, and can be measured at the corner 64, or can be an average slope for the sidewall 18b.

In one aspect, a first element configured to directly bond to a second element, is disclosed. The first element can include a nonconductive field region that has a surface defining at least a portion of a bonding surface of the first element. The surface of the nonconductive field region is prepared for direct bonding to the second element. The first element can include a conductive feature that has an upper surface defining at least a portion of the bonding surface of the first element, a lower surface opposite the upper surface, and a sidewall extending between the upper surface and the lower surface. An angle between the upper surface and the sidewall is about 75° or less.

In one embodiment, the angle between the upper surface and the sidewall is in a range of about 30° to 70°.

In one embodiment, the angle between the upper surface and the sidewall is in a range of about 30° to 60°.

In one embodiment, the angle between the upper surface and the sidewall is in a range of about 35° to 50°.

In one embodiment, the conductive feature is a contact pad and a thickness of the contact pad is in a range of about 1 μm to 2 μm. A width of the contact pad can be in a range of about 0.5 μm to 20 μm. The first element can further include a back-end-of-line structure below the nonconductive field region. The back-end-of-line structure can have a via electrically connected to the contact pad.

In one embodiment, the upper surface of the conductive feature is recessed relative to the surface of the nonconductive field region by about 2 nm to 20 nm.

In one aspect, a bonded structure is disclosed. The bonded structure can include a first element that includes a first nonconductive field region having a first surface defining at least a portion of a bonding surface of the first element, and a first conductive feature having a first upper surface defining at least a portion of the bonding surface of the first element, a first lower surface opposite the first upper surface, and a first sidewall extending between the first upper surface and the first lower surface. An angle between the first upper surface and the first sidewall is about 75° or less. The bonded structure can include a second element that includes a second nonconductive field region having a second surface directly bonded to the first surface of the first nonconductive field region, and a second conductive feature directly bonded to the first conductive feature.

In one embodiment, the angle between the first upper surface and the first sidewall is in a range of about 30° to 70°.

In one embodiment, the angle between the first upper surface and the first sidewall is in a range of about 30° to 60°.

In one embodiment, the angle between the first upper surface and the first sidewall is in a range of about 35° to 50°.

In one embodiment, the first conductive feature is a contact pad and a thickness of the contact pad is in a range of 1 μm to 2 μm, and a width of the contact pad is in a range of about 0.5 μm to 20 μm.

In one embodiment, the first upper surface of the first conductive feature is recessed relative to the first surface of the first nonconductive field region by about 2 nm to 20 nm.

In one embodiment, the second conductive feature has a second upper surface directly bonded to the first conductive feature, a second lower surface opposite the second upper surface of the second conductive feature, and a second sidewall extending between the second upper surface and the second lower surface of the second conductive feature. An angle between the second upper surface and the second sidewall of the second conductive feature can be about 75° or less.

In one aspect, a method of forming a conductive pad of an element is disclosed. The method can include forming a patterned resist layer over at least a portion of a surface of a dielectric layer, removing portions of the dielectric layer by etching to form a cavity having an angle between a sidewall of the cavity and the surface of the dielectric layer, providing a conductive material to at least partially fill the cavity with the conductive material, and polishing at least the surface of the dielectric layer to prepare for direct bonding. The angle is greater than about 105°.

In one embodiment, the patterned resist layer has a shape that conforms to a shape of the cavity, and the etching comprises dry etching.

In one embodiment, the etching includes isotropic etching.

In one embodiment, the angle between the sidewall of the cavity and the surface of the dielectric layer is in a range of about 110° to 150°.

In one embodiment, the sidewall of the cavity has a curvature.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. For example, while illustrated embodiments include preparation for direct hybrid bonding, the skilled artisan will appreciate that the techniques taught herein can be useful for direct metal bonding even in the absence of direct dielectric bonding. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. It is also contemplated that various combinations or sub-combinations of the specific features and aspects of the embodiments may be made and still fall within the scope. The accompanying claims and their equivalents are intended to cover such forms or modifications as would fall within the scope and spirit of the disclosure.

What is claimed is:

1. A first element configured to directly bond to a second element, the first element comprising:
a nonconductive field region having a surface defining at least a portion of a bonding surface of the first element, the surface of the nonconductive field region being prepared for direct bonding to the second element; and
a conductive feature having an upper surface defining at least a portion of the bonding surface of the first element, a lower surface opposite the upper surface, and a sidewall extending between the upper surface and the lower surface, wherein an angle between the upper surface and the sidewall is about 75° or less.

2. The first element of claim 1, wherein the angle between the upper surface and the sidewall is in a range of about 30° to 70°.

3. The first element of claim 1, wherein the angle between the upper surface and the sidewall is in a range of about 30° to 60°.

4. The first element of claim 1, wherein the angle between the upper surface and the sidewall is in a range of about 35° to 50°.

5. The first element of claim 1, wherein the conductive feature is a contact pad and a thickness of the contact pad is in a range of about 1 μm to 2 μm.

6. The first element of claim 5, wherein a width of the contact pad is in a range of about 0.5 μm to 20 μm.

7. The first element of claim 6, further comprising a back-end-of-line structure below the nonconductive field region, the back-end-of-line structure having a via electrically connected to the contact pad.

8. The first element of claim 1, wherein the upper surface of the conductive feature is recessed relative to the surface of the nonconductive field region by about 2 nm to 20 nm.

9. A bonded structure comprising:
a first element including a first nonconductive field region having a first surface defining at least a portion of a bonding surface of the first element, and a first conductive feature having a first upper surface defining at least a portion of the bonding surface of the first element, a first lower surface opposite the first upper surface, and a first sidewall extending between the first upper surface and the first lower surface, wherein an angle between the first upper surface and the first sidewall is about 75° or less; and
a second element including a second nonconductive field region having a second surface directly bonded to the first surface of the first nonconductive field region, and a second conductive feature directly bonded to the first conductive feature.

10. The bonded structure of claim 9, wherein the angle between the first upper surface and the first sidewall is in a range of about 30° to 70°.

11. The bonded structure of claim 9, wherein the angle between the first upper surface and the first sidewall is in a range of about 30° to 60°.

12. The bonded structure of claim 9, wherein the angle between the first upper surface and the first sidewall is in a range of about 35° to 50°.

13. The bonded structure of claim 9, wherein the first conductive feature is a contact pad and a thickness of the contact pad is in a range of 1 μm to 2 μm, and a width of the contact pad is in a range of about 0.5 μm to 20 μm.

14. The bonded structure of claim 9, wherein the first upper surface of the first conductive feature is recessed relative to the first surface of the first nonconductive field region by about 2 nm to 20 nm.

15. The bonded structure of claim 9, wherein the second conductive feature has a second upper surface directly bonded to the first conductive feature, a second lower surface opposite the second upper surface of the second conductive feature, and a second sidewall extending between the second upper surface and the second lower surface of the second conductive feature, wherein an angle between the second upper surface and the second sidewall of the second conductive feature is about 75° or less.

16. A method of forming a conductive pad of an element, the method comprising:
forming a patterned resist layer over at least a portion of a surface of a dielectric layer;
removing portions of the dielectric layer by etching to form a cavity having an angle between a sidewall of the cavity and the surface of the dielectric layer, the angle being greater than about 105°;
providing a conductive material to at least partially fill the cavity with the conductive material; and
polishing at least the surface of the dielectric layer to prepare for direct bonding.

17. The method of claim 16, wherein the patterned resist layer has a shape that conforms to a shape of the cavity, and the etching comprises dry etching.

18. The method of claim 16, wherein the etching comprises isotropic etching.

19. The method of claim 16, wherein the angle between the sidewall of the cavity and the surface of the dielectric layer is in a range of about 110° to 150°.

20. The method of claim 16, wherein the sidewall of the cavity has a curvature.
